(19) United States
(12) Patent Application Publication
(10) Pub. No.: US 2005/0221238 A1
(43) Pub. Date: Oct. 6, 2005

(54) Use of a reticle absorber material in reducing aberrations

(75) Inventor: Marcel Mathijs Theodore Marie Dierichs, Venlo (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 10/816,169

(22) Filed: Apr. 2, 2004

(51) Int. Cl. G03F 7/20

(52) U.S. Cl. 430/396; 430/5; 355/18

(57) ABSTRACT

A lithographic apparatus comprising a patterning reticle which has an aluminium absorber layer which improves imaging by eliminating or at least minimising the formation of aberrations in a patterned beam.

### FIELD OF INVENTION

The present invention relates to a lithographic apparatus and a device manufacturing method. In particular, the present invention relates to a lithographic apparatus designed to be used with radiation having a wavelength in the Extreme Ultra-Violet (EUV) range and wherein the lithographic apparatus comprises a patterning reticle which eliminates or at least minimises the formation of aberrations in a patterned beam.

### BACKGROUND OF THE INVENTION

A lithographic apparatus is a machine that applies a desired pattern onto a target portion of a substrate. Lithographic apparatus can be used, for example, in the manufacture of integrated circuits (ICs). In that circumstance a patterning structure, which is alternatively referred to as a mask or a reticle, may be used to generate a circuit pattern corresponding to an individual layer of the IC, and this pattern can be imaged onto a target portion (e.g. comprising part of, one or several dyes) on a substrate (e.g. a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the projection beam in a given direction (the “scanning”-direction) whilst synchronously scanning the substrate parallel or anti-parallel to this direction.

Between the reticle and the substrate is disposed a projection system for imaging the irradiated portion of the reticle onto the target portion of the substrate. The projection system includes components for directing, shaping or controlling the projection beam of irradiation, and these components typically include refractive optics, reflective optics, and/or catadioptric systems, for example.

An important feature in lithography is the size of features of the pattern applied to the substrate. It is desirable to produce apparatus capable of resolving features as small and close together as possible. A number of parameters affect the available resolution of features, and one of the most important of these is the wavelength of the radiation used to expose the pattern.

It is anticipated that the use of EUV lithography will enable the manufacture of feature sizes down to 32 nm using radiation with an EUV (Extreme Ultra-Violet) wavelength between 5 and 20 nm, and typically 13.5 nm. Radiation at this wavelength is absorbed in all materials and is therefore not suitable for use with refractive optics. The optics in a projection system for use with EUV lithography must therefore be based on mirrors, which can only operate in an ultra high vacuum (UHV) environment. The projection system is therefore enclosed in a Projection Optics Box (POB) which is kept under vacuum.

However, a significant difficulty in EUV lithography is designing a reticle to form a patterned beam with no phase induced spherical aberrations. Previous methods of forming reticles have involved forming a distributed Bragg reflector formed by a multilayer of forty or more layer pairs of, for example, Mo/Si or Mo/Be. The mask pattern is then formed by an overlying patterned absorber layer such as tantalum (Ta) or chromium (Cr). The multilayer and absorber layer must be relatively thick, many tens of wavelengths, and this, coupled with the necessity to illuminate the mask obliquely, introduces various aberrations (i.e. errors) in the projected image, as compared to an ideal, thin binary mask.

There are different types of aberrations such as odd aberrations and even aberrations. Examples of odd aberrations include tilt, coma, and 3-wave aberrations. Odd aberrations have an impact on XY displacement and have an asymmetrical behaviour in the XY direction. Examples of even aberrations include astigmatism, spherical and defocus aberrations. Even aberrations have an asymmetrical behaviour in the Z direction and affect the focus.

Aberrations are discussed in various publications. S. Bajt et al., Design and Performance of Capping Layers for EUV Multilayer Mirrors, SPIE Proceedings, Volume 5037 (2003) p236 describes variation of line widths and pattern shifts with angle of incidence of isolated structures and proposes correction by a suitable mask bias. C. G. Krautschik, M. Ito, I. Nishiyama, and K. Otaki, Impact of the EUV mask phase response on the asymmetry of Bossung curves as predicted by rigorous EUV mask simulations, SPIE Conference on Emerging Lithographic Technologies V, Santa Clara, Calif., SPIE Volume 4343 (March 2001) describes asymmetry of the Bossung curve through focus for isolated structures and indicates that different illumination angles experienced by horizontal and vertical lines causes an additional horizontal to vertical critical dimension (i.e. CD) bias through focus. Again, it is proposed to compensate for these effects through mask-sizing schemes. K Otaki, Asymmetric properties of the Aerial Image in Extreme Ultraviolet Lithograph, Jpn. J. Appl. Phys. Vol 39 (2000) pp 6819-6826, describes the influence of asymmetric diffraction when a thick mask is asymmetrically illuminated and notes the asymmetry in the aerial image.

EP-1 251 402-A discloses the idea of deliberately introducing aberrations into a projection lens to compensate for the other aberrations already present so as to minimize a merit function. Also disclosed is a method to compensate for Bossung tilt deriving from deviations from the correct 180° phase shift in a phase-shift mask (PSM).

U.S. Pat. No. 6,589,717 B1 relates to a method of selectively patterning a hard mask or reticle. A laser is used to cause deposition of hard mask material in locations forming the hard mask pattern. However, there is also disclosure of a mask blank (i.e. an unpatterned mask) used as a reticle in EUV lithography constructed from a Si wafer over which a plurality of alternating layers of Si and Mo are deposited. On the top surface of the alternating layers of Si and Mo, a buffer layer of SiO₂ is deposited. A layer of Al is then deposited and finally a Ni hard mask is deposited. The mask is normally etched to provide part of an integrated circuit. However, a mask blank as disclosed in U.S. Pat. No. 6,589,717 B1 if used in EUV lithography, would require defocus and focal tilt for the isolated lines compared to the dense lines. This is because the refractive index of Ni is 0.942+0.727i which is not very close to the ideal refractive index of 1. The influence of the Ni will therefore be detrimental to a resulting patterned beam. A patterned beam with artifacts would therefore be produced. The Ni layer is also relatively thick, many tens of wavelengths, meaning that its effect is not insignificant.

The methods of patterning a beam in the prior art are therefore not able to provide a patterned beam without imaging artifacts for use in EUV lithography.

Embodiments of the present invention provide a device manufacturing apparatus and method which improves imaging in EUV lithography.

### SUMMARY OF THE INVENTION

According to an aspect of the present invention there is provided a lithographic apparatus including, an illumination system for providing a projection beam of radiation, a support structure for supporting a patterning reticle, the patterning reticle serving to impart a pattern to the projection beam to form a patterned beam, a substrate table for holding a substrate, a projection system for projecting the patterned beam onto a target portion of the substrate, wherein the patterning reticle comprises an aluminium absorber layer with a protective top coating and wherein the patterning reticle improves imaging by eliminating or at least minimising the formation of aberrations in the patterned beam.

In embodiments of the present invention, the use of aluminium as an absorber overcomes difficulties obtained in currently used EUV reticles such as Ta and TaN which provide patterned beams with aberrations. Reticles currently in use result in a change in the phase of the diffraction order of the EUV radiation leading to deviations (i.e. aberrations) in the wave front. These aberrations need to be corrected or compensated for prior to imaging.

The aluminium absorber layer has the function of attenuating the projection beam and preferably remains stable on exposure to the projection beam.

The aluminium layer may form a substantially flat absorber surface. Conveniently, the aluminium layer may have a thickness which is substantially constant. Typically, the aluminium layer may have a thickness of about 50 nm to about 200 nm. Preferably, the aluminium layer may have a thickness of about 70 nm.

The protective coating may have a thickness of about 0.1 nm to about 5 nm. Conveniently, the protective coating may have a thickness of about 1 nm. Typically, the aluminium absorber layer may have a thin top coating selected from any of aluminium oxide (Al₂O₃), aluminium nitride (AlN), chromium oxide (Cr₂O₃), ruthenium (Ru), niobium (Nb) or any combination thereof. The protective coating may have a bulk reflectivity of less than 1%.

The patterning reticle may also comprise beneath the aluminium absorber layer a series of alternating layers of high index refraction material and low index refraction material such as described in U.S. Pat. No. 6,583,068 B2 which is incorporated herein by reference. The series of alternating layers act as a reflector in the patterning reticle. A high index refraction material has a refractive index wherein the real part has a relatively large deviation from 1.000. An example of a high index refraction material is Mo which has a refractive index of 0.921+0.0064i. A low index refraction material has a refractive index close to 1.000. An example of a low index refraction material is Si which has a refractive index of 0.999+0.0018i. The alternating layers of high and low index refraction material increases the contrast in the patterning structure. There may be about 20 to 100 alternating layers of high and low index refraction material. Preferably, there may be 60 layers of high and low index refraction material. Suitable combinations of high and low index refraction material may be as follows: Mo/Si; Ru/Si; Ru—Mo/Si; Rh/Si; Pd/Si; Pt/Si; Mo/Y; Ru—Mo/Y; and Ru—Mo/Y as described in EP 1260862 A1 which is incorporated herein by reference. Alternatively, alternating layers of Si alloys and Mo alloys may be used as described in U.S. 2002/017922 A1 which is incorporated herein by reference. The thickness of the high and low index refraction material may be about 1 nm to about 10 nm and preferably about 2 nm to about 5 nm.

Typically, between the alternating layers of high and low index refraction material there may be a barrier layer which prevents diffusion of one layer into another. The barrier layer may have a thickness of about 0.1 to about 0.5 nm and preferably about 0.25 nm. The barrier layer may, for example, be B₄C.

A preferred embodiment may have 60 alternating layers of Mo and Si wherein the Mo may have a thickness of about 2.09 nm and the Si may have a thickness of about 4.14 nm. Between the Mo and Si layers there may be a layer of B₄C which may have a thickness of about 0.25 nm.

Typically, the patterning reticle comprises a substrate of low coefficient of thermal expansion (CTE) material such as, for example, Zerodur (Trade Mark) obtained from Schott or ultra low expansion (ULE) material obtained from Corning. The substrate may form a bottom layer of the patterning structure.

Conveniently, the patterning reticle may also comprise a buffer layer which may be situated between the aluminium absorber layer and the series of alternating layers of high index refraction material and low index refraction material. The buffer layer may be formed from silicon dioxide (SiO₂), oxynitride (SiOₓN_{y}) or carbon. The buffer layer may have a thickness of about 5 nm to about 40 nm and may preferably be about 20 nm.

The projection system may comprise means for reflecting or refracting the projection beam.

Typically, the radiation used in the lithographic apparatus may have a wavelength corresponding to that of Extreme Ultra-Violet radiation (EUV). Preferably, the radiation used in the lithographic apparatus may have a wavelength of between about 5 nm to about 20 nm.

According to a further aspect of the present invention, there is provided a device manufacturing method including, providing a substrate, providing a projection beam of radiation using an illumination system, using a patterning reticle to impart a pattern to the projection beam to provide a patterned beam, projecting the patterned beam of radiation onto a target portion of the substrate, wherein the patterning reticle comprises an aluminium absorber layer with a protective top coating which improves imaging by eliminating or at least minimising the formation of aberrations in the patterned beam.

According to a still further aspect of the present invention, there is provided a patterning reticle for eliminating or substantially minimising aberrations in a patterned beam of irradiation in a lithographic apparatus, the patterning reticle including, a layer of material with a low coefficient of thermal expansion (CTE), and an aluminium absorber layer with a protective top coating, wherein the aluminium absorber layer imparts a pattern to a beam of radiation.

The patterning reticle may also comprise a series of alternating layers of high index refraction material and low index refraction material such as described in U.S. Pat. No. 6,583,068 B2 which is incorporated herein by reference. The alternating layers of high and low index refraction material may be situated on top of a layer of material with a low coefficient of thermal expansion (CTE).

Typically, between the layers of high and low index refraction material there may be a barrier layer such as B₄C.

Additionally, the patterning reticle may also comprise a buffer layer situated between the aluminium absorber layer and the alternating layers of high and low index refraction material.

According to a yet further aspect of the present invention there is provided a method of forming a patterning reticle for eliminating or substantially minimising aberrations in a patterned beam of irradiation in a lithographic apparatus, the method including, providing a layer of material which has a low coefficient of thermal expansion (CTE), depositing a series of alternating layers of high index refraction material and low index refraction material onto the layer of material with a low coefficient of thermal expansion (CTE), depositing a buffer layer onto the series of alternating layers of high index refraction material and low index refraction material, depositing an aluminium absorber layer onto said buffer layer, and forming a protective coating on top of the aluminium absorber layer.

Typically, the alternating layers of high index refraction material and low index refraction material may be deposited using ion beam deposition (IBD) or DC magnetic sputtering.

Optionally, between the different layers of high and low index refraction material there may be a barrier layer. The barrier layer may be deposited using any suitable deposition process such as sputtering.

The buffer layer may be deposited using RF magnetron sputtering.

Conveniently, the aluminium absorber layer may be deposited using DC magnetron sputtering.

The protective coating may be deposited by any suitable process.

Typically, a radiation-sensitive layer such as photoresist may then be deposited onto the protective coating. The photoresist may have a thickness of about 100-1000 nm and preferably about 200-600 nm. The radiation-sensitive layer may then be exposed to radiation such as deep ultraviolet (DUV) light or an electron beam (e-beam) to form a pattern in the photoresist.

A reactive ion etch process may then be used to transfer the pattern formed in the photoresist to the protective coating and the aluminium absorber layer. For example, a dry etching process may be used with a chlorine containing gas such as Cl₂ or BCl₃, or a fluorine containing gas such as NF₃.

The buffer layer may serve as an etch step layer to help produce a good etch profile in the overlying aluminium absorber layer. The buffer layer may also help to protect the underlying of alternating layers of high and low index refraction material from damage during the etch process. The buffer layer itself may be removed by dry etch or wet etch or a combination thereof. The etching of the buffer layer preferably does not damage the protective coating, the aluminium absorber layer or the series of alternating layers of high and low index refraction material. For example, the buffer layer may be dry etched with a gas containing fluorine such as CF₄ or C₄F₈. Alternatively, the buffer layer may be wet etched with an aqueous acidic solution such as hydrofluoric (HF) acid.

According to a further aspect of the present invention, there is provided a method of eliminating or at least substantially minimising aberrations in a patterned beam of radiation in a lithographic apparatus, the method including, providing a patterning reticle with an aluminium absorber layer with a protective top coating, and wherein the patterning reticle provides a patterned beam of radiation.

According to a yet further aspect of the present invention, there is provided integrated circuits (ICs), integrated optical systems, guidance and detection patterns for magnetic domain memories, liquid-crystal displays (LCDs) and thin-film magnetic heads formed using apparatus according to the present invention.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning structure” used herein should be broadly interpreted as referring to means that can be used to impart to a projection beam a pattern over its cross-section such as to create a pattern in a target portion of the substrate. It should be noted that the pattern imparted to the projection beam may not exactly correspond to the desired pattern in the target portion of the substrate. Generally, the pattern imparted to the projection beam will correspond to a particular functional layer in a device being created in the target portion, such as an integrated circuit.

Patterning structure may be transmissive or reflective. Examples of patterning structure include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure supports, i.e. bears the weight of, the patterning structure. It holds the patterning structure in a way depending on the orientation of the patterning structure, the design of the lithographic apparatus, and other conditions, such as for example whether or not the patterning structure is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning structure is at a desired position, for example with respect to the projection system.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “lens” herein may be considered as synonymous with the more general term “projection system”.

The illumination system may also encompass various types of optical components, including refractive, reflective, and catadioptric optical components for directing, shaping, or controlling the projection beam of radiation, and such components may also be referred to below, collectively or singularly, as a “lens”.

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

### BRIEF DESCRIPTION OF THE DRAWINGS

Embodiments of the present invention will now be described, by way of example only, with reference to the accompanying schematic drawings in which corresponding reference symbols indicate corresponding parts, and in which:

FIG. 1 depicts a typical lithographic apparatus;

FIG. 2 depicts a lithographic apparatus for use with Extreme Ultra-Violet (EUV) radiation according to an embodiment of the present invention;

FIG. 3 depicts a cross-sectional view of a reticle according to the present invention; and

FIG. 4 depicts Bossung curves for a reticle according to the prior art and a reticle according to an embodiment of the present invention.

### DETAILED DESCRIPTION OF EMBODIMENTS OF THE INVENTION

While specific embodiments of the invention have been described above, it will be appreciated that the invention may be practiced otherwise than as described. The description is not intended to limit the invention.

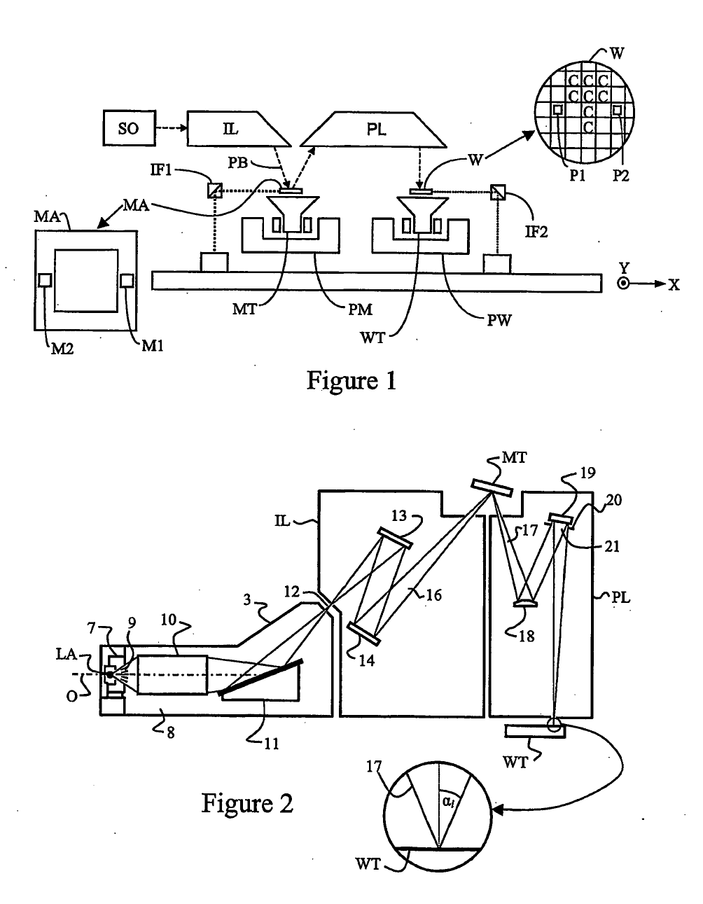

FIG. 1 schematically depicts a typical lithographic apparatus. The apparatus includes:
an illumination system (illuminator) IL for providing a projection beam PB of radiation (e.g. UV or EUV radiation).
a first support structure (e.g. a mask table) MT for supporting patterning structure (e.g. a mask) MA and connected to a first positioner PM for accurately positioning the patterning structure with respect to item PL;
a substrate table (e.g. a wafer table) WT for holding a substrate (e.g. a resist-coated wafer) W and connected to a second positioner PW for accurately positioning the substrate with respect to item PL; and
a projection system (e.g. a reflective projection lens) PL for imaging a pattern imparted to the projection beam PB by patterning structure MA onto a target portion C (e.g. comprising one or more dies) of the substrate W.

As here depicted, the apparatus is of a reflective type (e.g. employing a reflective mask or a programmable mirror array of a type as referred to above). Alternatively, the apparatus may be of a transmissive type (e.g. employing a transmissive mask).

The illuminator IL receives a beam of radiation from a radiation source SO. The source and the lithographic apparatus may be separate entities, for example when the source is a plasma discharge source. In such cases, the source is not considered to form part of the lithographic apparatus and the radiation beam is generally passed from the source SO to the illuminator IL with the aid of a radiation collector comprising for example suitable collecting mirrors and/or a spectral purity filter. In other cases the source may be integral part of the apparatus, for example when the source is a mercury lamp. The source SO and the illuminator IL, may be referred to as a radiation system.

The illuminator IL may comprise adjustable elements for adjusting the angular intensity distribution of the beam. Generally, at least the outer and/or inner radial extent (commonly referred to as σ-outer and σ-inner, respectively) of the intensity distribution in a pupil plane of the illuminator can be adjusted. The illuminator provides a conditioned beam of radiation, referred to as the projection beam PB, having a desired uniformity and intensity distribution in its cross-section.

The projection beam PB is incident on the mask MA, which is held on the mask table MT. Being reflected by the mask MA, the projection beam PB passes through the lens PL, which focuses the beam onto a target portion C of the substrate W. With the aid of the second positioning means PW and position sensor IF2 (e.g. an interferometric device), the substrate table WT can be moved accurately, e.g. so as to position different target portions C in the path of the beam PB. Similarly, the first positioning means PM and position sensor IF1 can be used to accurately position the mask MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning means PM and PW. However, in the case of a stepper (as opposed to a scanner) the mask table MT may be connected to a short stroke actuator only, or may be fixed. Mask MA and substrate W may be aligned using mask alignment marks M1, M2 and substrate alignment marks P1, P2.

The depicted apparatus can be used in the following preferred modes:

1. In step mode, the mask table MT and the substrate table WT are kept essentially stationary, while an entire pattern imparted to the projection beam is projected onto a target portion C in one go (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the projection beam is projected onto a target portion C (i.e. a single dynamic exposure). The velocity and direction of the substrate table WT relative to the mask table MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning structure, and the substrate table WT is moved or scanned while a pattern imparted to the projection beam is projected onto a target portion C. In this mode, generally a pulsed radiation source is employed and the programmable patterning structure is updated as required after each movement of the substrate table WT or in between successive radiation pulses during a scan. This mode of operation can be readily applied to maskless lithography that utilizes programmable patterning structure, such as a programmable mirror array of a type as referred to above.

Combinations and/or variations on the above described modes of use or entirely different modes of use may also be employed.

FIG. 2 shows a side view of an EUV lithographic apparatus in accordance with an embodiment of the invention. It will be noted that, although the arrangement is different to that of the apparatus shown in FIG. 1, the principle of operation is similar. The apparatus comprises a source-collector module or radiation unit 3, an illumination system IL, and a projection system PL. Radiation unit 3 is provided with a radiation source LA which may employ a gas or vapor, such as for example Xe gas or Li vapor in which a very hot discharge plasma is created so as to emit radiation in the EUV range of the electromagnetic radiation spectrum. The discharge plasma is created by causing a partially ionized plasma of an electrical discharge to collapse onto the optical axis O. Partial pressures of 0.1 mbar of Xe, Li vapor or any other suitable gas or vapor may be required for efficient generation of the radiation. The radiation emitted by radiation source LA is passed from the source chamber 7 into collector chamber 8 via a gas barrier structure or “foil trap” 9. The gas barrier structure comprises a channel structure such as, for instance, described in detail in European patent applications EP-A-1 233 468 and EP-A-1 057 079, which are incorporated herein by reference.

The collector chamber 8 comprises a radiation collector 10 which is formed, for example, by a grazing incidence collector. Radiation passed by collector 10 is reflected from a grating spectral purity filter 11 to be focused in a virtual source point 12 at an aperture in the collector chamber 8. From chamber 8, the projection beam 16 is reflected in illumination system IL via normal incidence reflectors 13, 14 onto a reticle or mask positioned on reticle or mask table MT. A patterned beam 17 is formed which is imaged by projection system PL via reflective elements 18, 19 onto wafer stage or substrate table WT. More elements than shown may generally be present in the illumination system IL and projection system PL.

One of the reflective elements 19 has in front of it an NA stop disc 20 having an aperture 21 therethrough. The size of the aperture 21 determines the angle Di subtended by the radiation beam 17 as it strikes the substrate table WT.

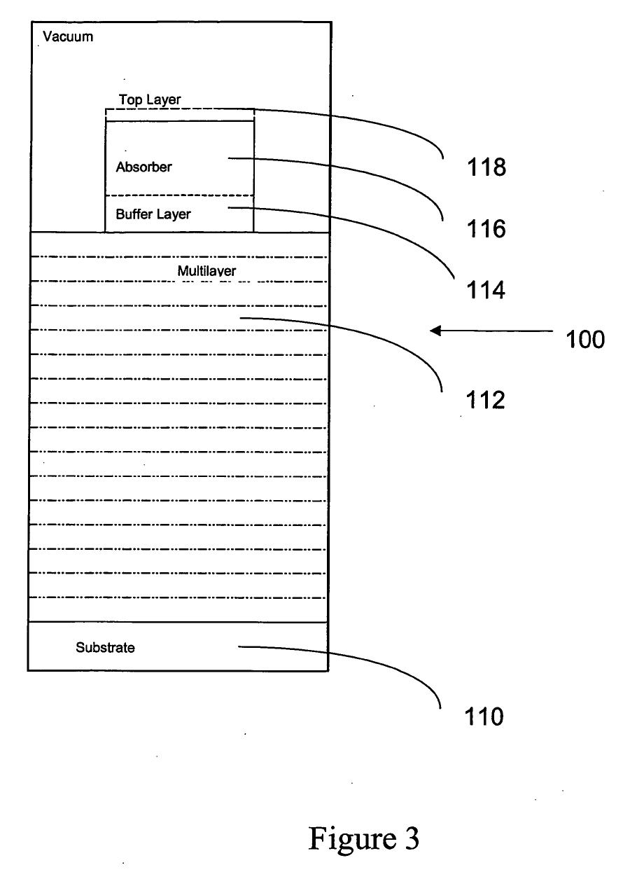

FIG. 3 is a cross-sectional view of a reticle, generally designated 100, according to an embodiment of the present invention.

The reticle 100 comprises a bottom substrate material 110 of Zerodur (Trade Name). On top of the substrate material 110 there is a series of sixty alternating layers of Mo and Si, generally designated 112. The Mo layers have a thickness of about 2.09 nm and the Si layers have a thickness of about 4.14 nm. Between each Mo and Si layer there is a barrier layer of B₄C which has a thickness of about 0.25 nm.

On top of the alternating layers of Mo and Si there is a buffer layer 114 of silicon dioxide with a thickness of about 20 nm.

There is then an aluminium absorber layer 116 on top of the buffer layer 114. The aluminium absorber layer has a thickness of about 70 nm.

On top of the aluminium absorber layer 116 there is a protective layer 118 of aluminium oxide. The protective aluminium oxide layer 118 has a thickness of about 1 nm.

The alternating layers of Mo and Si are deposited using an ion beam deposition (IBD) technique. The barrier layers are deposited using a sputtering technique. The buffer layer 114 of silicon dioxide is deposited using RF magnetron sputtering. The aluminium absorber layer 116 is deposited using DC magnetron sputtering.

A radiation-sensitive layer of photoresist is deposited onto the protective coating with a thickness of about 400 nm. The photoresist is then exposed to deep ultraviolet (DUV) light which forms a pattern in the photoresist. A reactive ion etch process is then used to transfer the pattern formed in the photoresist to the aluminium oxide protective coating 118 and the aluminium absorber layer 116. A dry etching process using Cl₂ is used to remove the aluminium oxide protective coating 118 and the aluminium absorber layer 114. The buffer layer 114 acts as an etch stop layer and protects the underlying layers of Mo and Si. The buffer layer 114 is then removed with a dry etch process using CF₄.

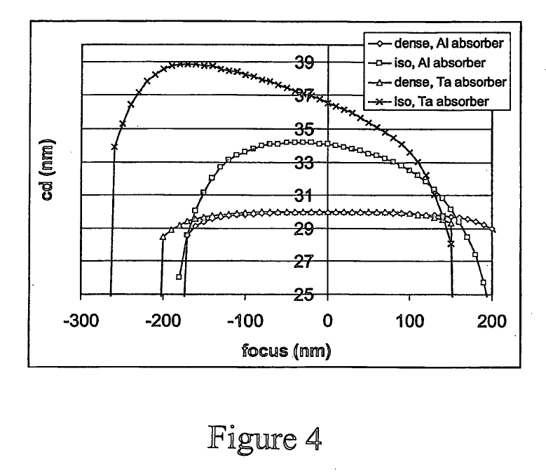

FIG. 4 illustrates Bossung curves obtained for EUV reticles with an absorber surface made from Ta and Al. Bossung curves show critical dimension (i.e. line widths) versus focus for different exposure doses. It is clear from FIG. 4 that the Bossung curve for both the isolated lines (i.e. iso) and dense lines when the reticle has an absorber surface made from Al are highly symmetrical. This means that no defocusing and focal tilt is required for the isolated lines in comparison to the dense lines prior to imaging.

The Al reticle producing the results shown in FIG. 4 is the reticle as shown in FIG. 3.

In contrast, the Bossung curve for the isolated line when the reticle has an absorber surface made from Ta is asymmetrical. The dense line is symmetrical. The values for the Ta Bossung curves shown in FIG. 4 are obtained when a 50 nm thick Ta absorber is used.

To prevent aberrations in a patterned beam of EUV radiation it has been found that a material with a refractive index as close as possible to 1.0 is preferred. Al has a refractive index of 1.0025 and is able to form a reticle providing a patterned beam with no or substantially minimised aberrations. This is shown by the symmetrical plots for the isolated and dense lines in FIG. 4 for the Al absorber.

In contrast, Ta has a refractive index of 0.9439+0.0408i which is not very close to the ideal refractive index of 1.0. A reticle made from Ta therefore produces aberrations in patterned beams. This is shown by the asymmetrical plots in FIG. 4.

By using Al as the absorber material in the reticle, spherical aberrations in a patterned beam of EUV radiation are therefore eliminated or at least substantially minimised. There is therefore no need for the patterned beam to undergo a process of correction such as defocusing and focal tilt prior to imaging a portion of a substrate. For example, in contrast to other processes there is no need to deliberately introduce aberrations into the projection system to control and/or counteract aberrations formed by the reticle.

While specific embodiments of the invention have been described above, it will be appreciated that departures from the above described embodiments may still fall within the scope of the invention. For example, the aluminium absorber material in the reticle may be coated with any suitable protective coating which does not produce aberrations in a patterned beam. Furthermore, the apparatus has been described for use with EUV radiation but it will be appreciated that radiation of other wavelengths may also be used.

1. A lithographic apparatus comprising:
an illumination system for providing a projection beam of radiation;
a support structure for supporting a patterning structure, the patterning structure serving to impart a pattern to the projection beam to form a patterned beam;
a substrate table for holding a substrate;
a projection system for projecting the patterned beam onto a target portion of the substrate;
wherein the patterning structure comprises an aluminium absorber layer with a protective top coating and wherein the patterning structure improves imaging by eliminating or at least minimising the formation of aberrations in the patterned beam.

2. A lithographic apparatus according to claim 1, wherein the aluminium forms a substantially flat absorber surface.

3. A lithographic apparatus according to claim 1, wherein the aluminium has a thickness which is substantially constant.

4. A lithographic apparatus according to claim 1, wherein the aluminium has a thickness of about 50 nm to about 200 nm.

5. A lithographic apparatus according to claim 1, wherein the aluminium has a thickness of about 70 nm.

6. A lithographic apparatus according to claim 1, wherein the aluminium has a protective top coating of any of aluminium oxide, aluminium nitride, chromium oxide, ruthenium, niobium or any combination thereof.

7. A lithographic apparatus according to claim 6, wherein the protective top coating has a thickness of about 0.1 nm to about 5 nm.

8. A lithographic apparatus according to claim 6, wherein the protective top coating has a thickness of about 1 nm.

9. A lithographic apparatus according to claim 1, wherein the patterning structure comprises a bottom substrate material with a low coefficient of thermal expansion (CTE).

10. A lithographic apparatus according to claim 1, wherein beneath the aluminium absorber layer there is a series of alternating layers of high index refraction material and low index refraction material.

11. A lithographic apparatus according to claim 10, wherein there are about 20 to about 80 layers of high and low index refraction material.

12. A lithographic apparatus according to claim 10, wherein combinations of high and low index refraction material are as follows: Mo/Si; Ru/Si; Ru—Mo/Si; Rh/Si;
Pd/Si; Pt/Si; Mo/Y; Ru—Mo/Y; or Mo alloys and Si alloys.

13. A lithographic apparatus according to claim 10, wherein the high and low index refraction material have a thickness of about 1 nm to about 10 nm.

14. A lithographic apparatus according to claim 10, wherein between the high and low index refraction material there is a barrier layer.

15. A lithographic apparatus according to claim 1, wherein the patterning structure further comprises a buffer layer.

16. A lithographic apparatus according to claim 15, wherein the buffer layer is silicon dioxide.

17. A lithographic apparatus according to claim 1, wherein the projection system comprises means for reflecting or refracting the projection beam.

18. A lithographic apparatus according to claim 1, wherein the radiation is Extreme Ultra-Violet radiation (EUV).

19. A lithographic apparatus according to claim 1, wherein the radiation has a wavelength of between about 5 nm and about 20 nm.

20. A device manufacturing method comprising:
projecting a patterned beam of radiation onto a target portion of a substrate; and
minimizing formation of aberrations in the patterned beam by using a patterning structure having an aluminium absorber layer with a protective top coating.

21. A device manufacturing method according to claim 20, wherein the aluminium forms a substantially flat surface.

22. A device manufacturing method according to claim 20, wherein the aluminium has a thickness which is substantially constant.

23. A device manufacturing method according to claim 20, wherein the aluminium has a thickness of about 50 to about 200 nm.

24. A device manufacturing method according to claim 20, wherein the aluminium has a thickness of about 70 nm.

25. A device manufacturing method according to claim 20, wherein the aluminium has a protective top coating of any of aluminium oxide, aluminium nitride, chromium oxide, ruthenium, niobium or any combination thereof.

26. A device manufacturing method according to claim 20, wherein the protective top coating has a thickness of about 0.1 to about 5 nm.

27. A device manufacturing method according to claim 20, wherein the protective top coating has a thickness of about 1 nm.

28. A device manufacturing method according to claim 20, wherein the patterning structure comprises a material with a low CTE.

29. A device manufacturing method according to claim 20, wherein beneath the aluminium absorber layer there is a series of alternating layers of high index refraction material and low index refraction material.

30. A device manufacturing method according to claim 29, wherein there are about 20 to 80 layers of high and low index refraction material.

31. A device manufacturing method according to claim 29, wherein combinations of high and low index refraction material are as follows: Mo/Si; Ru/Si; Ru—Mo/Si;
Rh/Si; Pd/Si; Pt/Si; Mo/Y; Ru—Mo/Y; Ru—Mo/Y; or Mo alloys and Si alloys.

32. A device manufacturing method according to claim 29, wherein the high and low index refraction material have a thickness of about 1 nm to about 10 nm.

33. A device manufacturing method according to claim 29, wherein between the high and low index refraction material there is a barrier layer.

34. A device manufacturing method according to claim 20, wherein the patterning structure further comprises a buffer layer.

35. A device manufacturing method according to claim 34, wherein the buffer layer is silicon dioxide.

36. A device manufacturing method according to claim 20, wherein the beam is projected using reflective or refractive means.

37. A device manufacturing method according to claim 20, wherein the radiation is Extreme Ultra-Violet radiation (EUV).

38. A device manufacturing method according to claim 20, wherein the radiation has a wavelength of between about 5 nm and about 20 nm.

39. A patterning structure comprising:
a layer of material with a low coefficient of thermal expansion (CTE); and
an aluminium coating with a protective top coating;
wherein the aluminium coating is an absorber layer which imparts the pattern to a beam of radiation.

40. A patterning structure according to claim 39, wherein the aluminium comprises a substantially flat absorber surface.

41. A patterning structure according to claim 39, wherein the aluminium has a thickness which is substantially constant.

42. A patterning structure according to claim 39, wherein the aluminium has a thickness of about 50 nm to about 200 nm.

43. A patterning structure according to claim 39, wherein the aluminium has a thickness of about 70 nm.

44. A patterning structure according to claim 39, wherein the aluminium has a protective top coating of any of aluminium oxide, aluminium nitride, chromium oxide, ruthenium, niobium or any combination thereof.

45. A patterning structure according to claim 44, wherein the protective top coating has a thickness of about 0.1 nm to about 5 nm.

46. A patterning structure according to claim 44, wherein the protective top coating has a thickness of about 1 nm.

47. A patterning structure according to claim 39, wherein the patterning structure comprises a bottom substrate material with a low coefficient of thermal expansion (CTE).

48. A patterning structure according to claim 39, wherein beneath the aluminium absorber layer there is a series of alternating layers of high index refraction material and low index refraction material.

49. A patterning structure according to claim 48, wherein there are about 20 to about 80 layers of high and low index refraction material.

50. A patterning structure according to claim 48, wherein combinations of high and low index refraction material are as follows: Mo/Si; Ru/Si; Ru—Mo/Si; Rh/Si;
Pd/Si; Pt/Si; Mo/Y; Ru—Mo/Y; or Mo alloys and Si alloys.

51. A patterning structure according to claim 48, wherein the high and low index refraction material have a thickness of about 1 nm to about 10 nm.

52. A patterning structure according to claim 48, wherein between the high and low index refraction material there is a barrier layer.

53. A patterning structure according to claim 39, wherein the patterning structure further comprises a buffer layer.

54. A patterning structure according to claim 53, wherein the buffer layer is silicon dioxide.

55. A method of forming a patterning structure for use in a lithographic apparatus, the method comprising:
providing a layer of material which has a low coefficient of thermal expansion (CTE);
depositing a series of alternating layers of high index refraction material and low index refraction material onto the layer of material with a low coefficient of thermal expansion (CTE);
depositing a buffer layer onto the series of alternating layers of high index refraction material and low index material;
depositing an aluminium absorber layer onto said buffer layer; and
forming a protective coating on top of the aluminium absorber.

56. A method according to claim 55 wherein a radiation-sensitive layer is deposited onto the protective coating and is then etched to form a pattern.

57. A method according to claim 55 wherein the etching process comprises a reactive ion etch process and dry etching processes.

58. Integrated circuits (ICs) made using the lithographic apparatus according to claim 1.

59. Integrated optical systems made using the lithographic apparatus according to claim 1.

60. Guidance and detection patterns for magnetic domain memories made using the lithographic apparatus according to claim 1.

61. Liquid crystal displays (LCDs) made using the lithographic apparatus according to claim 1.

62. Thin-film magnetic heads made using the lithographic apparatus according to claim 1.
